(19) United States
(12) Patent Application Publication
(10) Pub. No.: US 2026/0333540 A1
(43) Pub. Date: Oct. 22, 2026

(54) DC/DC CONVERTER

(71) Applicant: Mitsubishi Electric Corporation, Tokyo (JP)

(72) Inventors: Hiroyuki YOSHINO, Chiyoda-ku, Tokyo (JP); Takashi HIRATSUKA, Chiyoda-ku, Tokyo (JP); Hiroyasu IWABUKI, Chiyoda-ku, Tokyo (JP)

(73) Assignee: Mitsubishi Electric Corporation, Tokyo (JP)

(21) Appl. No.: 18/997,892

(22) PCT Filed: Jul. 29, 2022
(86) PCT No.: PCT/JP2022/029332

§ 371 Date: Jan. 23, 2025

(51) Int. Cl. H05B 45/36; B60Q 1/14; H02M 3/00; H05B 45/305; H05B 45/38; H10D 8/60

(52) U.S. Cl. CPC H05B 45/36; B60Q 1/1415; H05B 45/305; H05B 45/38; H02M 3/003; H10D 8/605

(57) ABSTRACT

A DC/DC converter is a DC/DC converter of an asynchronous type. The DC/DC converter includes an inductor, a switching element, a diode, and a controller to control the switching element. The switching element is connected to the inductor in series. The diode is connected between power lines and a headlight. The controller controls the switching element such that a switching frequency of the switching element becomes higher than an upper limit frequency of a predetermined frequency band. The diode includes a first capacitance and a second capacitance. The first capacitance is a capacitance of a rectification path through which a forward current of the diode flows. The second capacitance is a capacitance of a current path formed in parallel with the rectification path.

### TECHNICAL FIELD

The present disclosure relates to a DC/DC converter, and in particular, to a DC/DC converter of an asynchronous type.

### BACKGROUND ART

WO 2015/186404 (PTL 1) discloses a multi-phase type DC/DC converter. The DC/DC converter includes a plurality of (N) converter portions. Each converter portion is a converter of an asynchronous type, including an inductor, a switching element, and a diode. To prevent noise generated by switching (hereinafter referred to as “switching noise”) from interfering with a signal in a broadcast band (for example, an AM broadcast band), the product of a switching frequency F of the switching element of each converter and the number N of operating converter portions is set to be outside the range of the broadcast band described above.

### CITATION LIST

### Patent Literature

PTL 1: WO 2015/186404

### SUMMARY OF INVENTION

### Technical Problem

When a switching frequency of a switching element of each DC/DC converter is set to be lower than a predetermined frequency band (for example, the broadcast band described above), even if the switching frequency is set such that the product of switching frequency F and the number N of operating converter portions is outside the range of the broadcast band, a harmonic frequency of switching frequency F may be within a frequency band of the broadcast band described above. As a result, switching noise may interfere with a signal in the broadcast band described above. Accordingly, from the viewpoint of noise reduction, it is conceivable to set switching frequency F to be higher than an upper limit frequency of the broadcast band described above. However, when switching frequency F is set to be higher than the upper limit frequency described above, power conversion efficiency of the DC/DC converter may be significantly reduced due to increased switching loss.

The present disclosure has been made to solve the aforementioned problem, and an object thereof is to suppress reduction in power conversion efficiency, while avoiding interference of noise with a signal having a frequency within a predetermined frequency band, in a DC/DC converter of an asynchronous type.

### Solution to Problem

The DC/DC converter in the present disclosure is a DC/DC converter of an asynchronous type. The DC/DC converter includes an inductor, a switching element, a diode, and a controller to control the switching element. The switching element is connected to the inductor in series. The diode is connected to the inductor and the switching element. The controller controls the switching element such that a switching frequency of the switching element becomes higher than an upper limit frequency of a predetermined frequency band. The diode includes a first capacitance and a second capacitance. The first capacitance is a capacitance of a rectification path through which a forward current of the diode flows. The second capacitance is a capacitance of a current path formed in parallel with the rectification path.

### Advantageous Effects of Invention

According to the present disclosure, it is possible to suppress reduction in power conversion efficiency, while avoiding interference of noise with a signal having a frequency within a predetermined frequency band, in a DC/DC converter of an asynchronous type.

### BRIEF DESCRIPTION OF DRAWINGS

FIG. 1 is a schematic view of a vehicle illustrated as an example of a facility including a DC/DC converter according to an embodiment.

FIG. 2 is a view illustrating an example of a configuration of the DC/DC converter.

FIG. 3 is a view illustrating an example of a configuration of a load for the DC/DC converter.

FIG. 4 is a view illustrating an example of a configuration of a diode shown in FIG. 2.

FIG. 5 is a view illustrating an equivalent circuit of the diode.

FIG. 6 is a view illustrating an example of transition of a drain-source voltage when a switching element is turned on.

FIG. 7 is a view illustrating an example of the relation between a total loss of the DC/DC converter and a switching frequency of the switching element.

FIG. 8 is a view illustrating an example of the relation between a total loss difference between DC/DC converters and the switching frequency of the switching element.

FIG. 9 is a view illustrating an example of a spectrum of frequency of noise generated due to switching operation of the switching element of the DC/DC converter.

FIG. 10 is a view illustrating an example of a configuration of a DC/DC converter in a variation.

### DESCRIPTION OF EMBODIMENTS

Hereinafter, an embodiment of the present disclosure will be described in detail with reference to the drawings, in which identical or corresponding parts will be designated by the same reference numerals, and the description thereof will not be repeated.

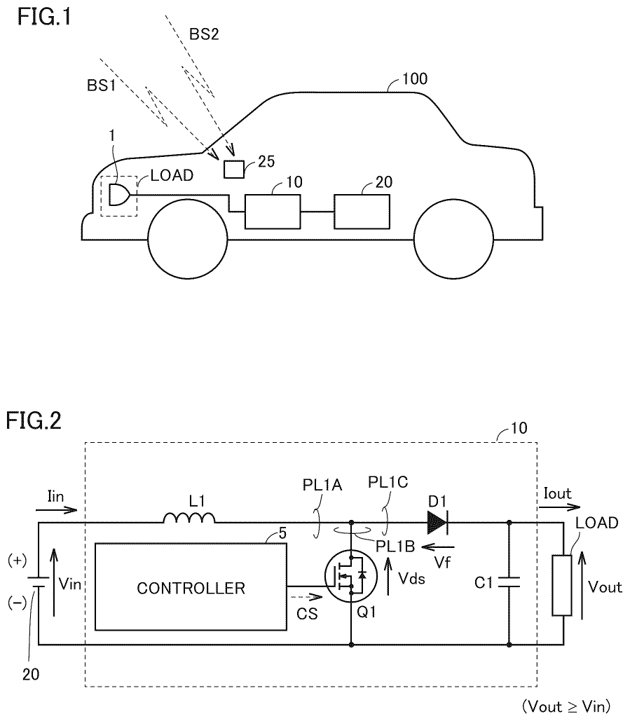

FIG. 1 is a schematic view of a vehicle illustrated as an example of a facility including a DC/DC converter according to the embodiment. Referring to FIG. 1, a vehicle 100 includes a load LOAD, a DC/DC converter 10, a battery 20, and a radio 25.

Load LOAD includes a headlight 1. Headlight 1 emits light forward in a direction in which vehicle 100 travels.

DC/DC converter 10 is connected to load LOAD and battery 20, and receives power from battery 20 and drives load LOAD. In the present example, DC/DC converter 10 is a boost converter, and a drive voltage of load LOAD is 30 V to 70 V.

Battery 20 is used as a power source for DC/DC converter 10. Battery 20 has a voltage of 12 V, for example. Vehicle 100 is a gasoline vehicle, or an electrically powered vehicle such as an electric vehicle or a hybrid vehicle, and when vehicle 100 is an electric vehicle or a hybrid vehicle, battery 20 corresponds to an auxiliary battery.

The relation of connection among the components such as DC/DC converter 10 and battery 20 is not limited to the example in FIG. 1. As an example, DC/DC converter 10 and battery 20 may be disposed at positions close to headlight 1 (for example, within an engine compartment).

Radio 25 is configured, for example, to receive a broadcast signal BS1 having a frequency within an AM broadcast band, and produce the sound of a program for AM broadcast. Similarly, radio 25 is also configured to receive a broadcast signal BS2 having a frequency within an FM broadcast band, and produce the sound of a program for FM broadcast. In the present embodiment, it is assumed that the AM broadcast band is a frequency band of 0.52 MHz to 1.71 MHz, for example, and the FM broadcast band is a frequency band of 76 MHz to 108 MHZ, for example.

FIG. 2 is a view illustrating an example of a configuration of DC/DC converter 10. Referring to FIG. 2, DC/DC converter 10 is a DC/DC converter of an asynchronous type, and includes a switching element Q1, an inductor L1, a diode D1, a capacitor C1, and a controller 5.

Inductor L1 is connected between a positive electrode node of battery 20 and switching element Q1. Various components may be provided between the positive electrode node of battery 20 and inductor L1. The various components include, for example, a harness for supplying power from battery 20, a protection circuit for protecting DC/DC converter 10 when battery 20 is erroneously connected in reverse polarity, or a filter circuit for reducing noise and voltage fluctuation.

Although switching element Q1 is a metal-oxide-semiconductor field effect transistor (MOSFET) in this example, it may be an insulated gate bipolar transistor (IGBT) or the like. Switching element Q1 is connected to inductor L1 in series. That is, switching element Q1 is connected between inductor L1 and a negative electrode node of battery 20. For example, a harness for supplying power from battery 20 may be provided between the negative electrode node of battery 20 and switching element Q1. A voltage between a drain and a source of switching element Q1 is referred to as a voltage Vds.

Diode D1 is connected between power lines PL1A, PL1B and load LOAD. A buck converter (described later), a harness for supplying power to headlight 1, or the like may be provided between diode D1 and headlight 1 of load LOAD. Each of power lines PL1A and PL1B is provided between inductor L1 and switching element Q1, and is connected to an anode of diode D1 through a power line PL1C. Each of power lines PL1A, PL1B, and PL1C may be replaced by an electric path formed of a copper foil pattern or the like formed on a circuit board.

Diode D1 is a trench-type Schottky diode. A forward voltage (voltage drop) of diode D1 is referred to as a forward voltage Vf. When the drive voltage of load LOAD is 30 V to 70 V, a withstand voltage of diode D1 with respect to a reverse voltage is 40 V to 100 V, for example. Capacitor C1 is provided to smooth an output voltage Vout.

Controller 5 outputs a pulse modulation signal such as a pulse width modulation (PWM) signal, as a control signal CS, through a gate drive circuit (not shown). Control signal CS is inputted to a gate terminal of switching element Q1, and is used for switching control. A switching frequency of switching element Q1 is determined according to a carrier frequency for PWM control. Controller 5 controls output voltage Vout of DC/DC converter 10 by controlling a duty ratio between ON and OFF of switching element Q1.

When switching element Q1 in ON, an input current Iin of DC/DC converter 10 flows into switching element Q1 through inductor L1. During an ON period of switching element Q1, inductor L1 stores energy of input current Iin provided from battery 20. The amount of the stored energy varies depending on the duty ratio between ON and OFF of switching element Q1.

On the other hand, when switching element Q1 is OFF, input current Iin flows into diode D1 through inductor L1. During an OFF period of switching element Q1, inductor L1 supplies the energy stored during the ON period of switching element Q1, in addition to input current Iin, to capacitor C1 and load LOAD through diode D1. Thereby, an input voltage Vin of DC/DC converter 10 is boosted to output voltage Vout (Vout≥Vin).

Thus, DC/DC converter 10 boosts input voltage Vin provided from battery 20, and supplies the boosted voltage (Vout) and power to load LOAD and thereby drives load LOAD. In this example, input voltage Vin is 12 V, and output voltage Vout is 30 V to 70 V.

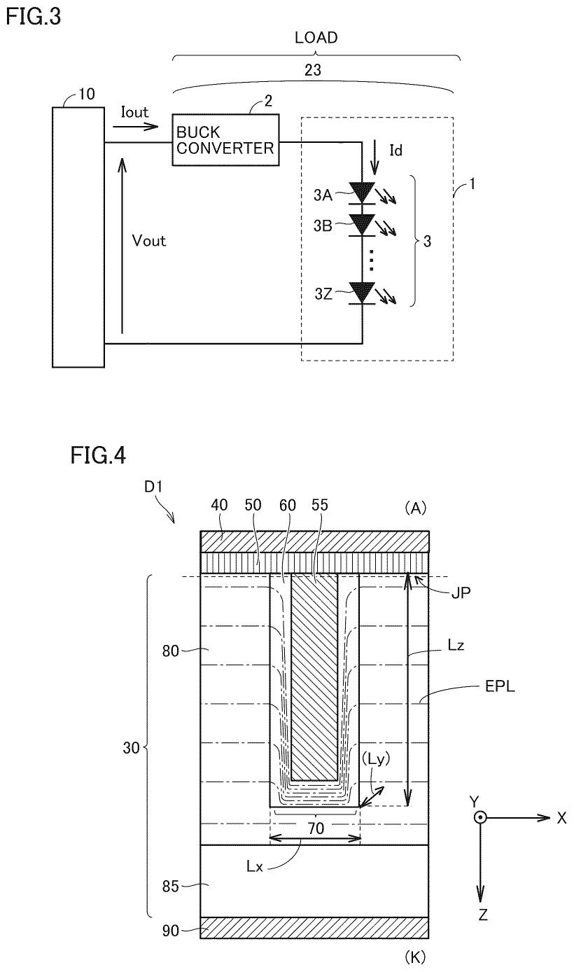

FIG. 3 is a view illustrating an example of a configuration of load LOAD for DC/DC converter 10. Referring to FIG. 3, load LOAD includes a light emitting diode (LED) array 3 disposed within headlight 1, and a buck converter 2 which supplies a predetermined current to LED array 3. Buck converter 2 may be disposed on the same circuit board as that on which DC/DC converter 10 is disposed, or may be disposed together with LED array 3 within headlight 1. In the present embodiment, a set of buck converter 2 and LED array 3 is also referred to as a unit 23.

LED array 3 is configured to include LEDs 3A to 3Z. In the present embodiment, LEDs 3A to 3Z are connected in series in LED array 3. Brightness of each of LEDs 3A to 3Z is determined depending on a current Id supplied to LED array 3.

Typically, the number of LEDs 3A to 3Z in LED array 3 is large. For example, when the number of LEDs 3A to 3Z is eight and current Id of about 1 A to 1.5 A is supplied, a forward voltage of LED array 3 (that is, the sum of forward voltages of LEDs 3A to 3Z) is typically about 24 V to 27 V. Therefore, in many cases, a voltage applied to LED array 3 becomes higher than the voltage of battery 20 (for example, 12 V). Accordingly, DC/DC converter 10 connected to battery 20 is typically a boost converter.

Buck converter 2 lowers output voltage Vout of DC/DC converter 10, and provides the lowered voltage to LED array 3. Buck converter 2 monitors an output current of buck converter 2, that is, current Id of LED array 3, using a current sense resistor, and controls the lowered voltage such that the monitored value matches a predetermined target current value (for example, 1 A). Thereby, constant current Id is supplied to LED array 3.

In the case of the configuration of the load illustrated in FIG. 3, DC/DC converter 10 controls the boosted output voltage (Vout) to be constant. In DC/DC converter 10, controller 5 monitors the boosted output voltage (Vout), and controls output voltage Vout such that the monitored voltage value matches a predetermined target voltage value (30 V to 70 V in the case of the present embodiment). Thereby, constant output voltage Vout is supplied to the load.

Controller 5 may be an analog circuit including an operational amplifier and a comparator, or may be a digital circuit including an analog-to-digital converter (ADC) and a circuit such as a field programmable gate array (FPGA), a central processing unit (CPU), or a micro controller unit (MCU). Alternatively, controller 5 may include both the analog circuit and the digital circuit described above.

Controller 5 may monitor a current of inductor L1 or switching element Q1 of DC/DC converter 10 (a current between a drain and a source in the case of a MOSFET) using a current sense resistor, and may use the monitored current as a triangular wave for comparison of pulse modulation (a current mode control method).

It should be noted that load LOAD may be configured to include a plurality of units 23 provided in parallel. Some or all buck converters 2 in the plurality of units 23 may be disposed on the same circuit board as that on which DC/DC converter 10 is disposed.

Alternatively, buck converter 2 may be eliminated. When buck converter 2 is eliminated, DC/DC converter 10 supplies constant current Id to LED array 3. In this case, DC/DC converter 10 monitors an output current of DC/DC converter 10, that is, current Id of LED array 3, using a current sense resistor, and controls the boosted output voltage (Vout) such that the monitored current value matches a predetermined target current value (for example, 1 A). Thereby, constant current Id is supplied to LED array 3.

FIG. 4 is a view illustrating an example of a configuration of diode D1 shown in FIG. 2. In the following description, FIG. 2 will be referred to as appropriate. Referring to FIG. 4, an X direction and a Y direction are perpendicular to each other, and are both perpendicular to a Z direction. The Z direction is a direction in which a forward current of diode D1 flows, that is, a direction from the anode to a cathode of diode D1. FIG. 4 is a cross sectional view of diode D1 viewed in the Y direction.

Unlike a planar-type diode, diode D1 has a trench portion 70 extending in the Z direction. Although FIG. 4 shows one trench portion 70 for easier understanding, diode D1 actually has a plurality of trench portions 70 provided periodically in the X direction. It is assumed that trench portion 70 has a width Lx in the X direction, a width Ly in the Y direction, and a depth Lz in the Z direction. That is, the shape of trench portion 70 is represented by widths Lx, Ly and depth Lz.

Diode D1 includes an anode electrode layer 40, a metal layer 50, a polysilicon layer 55, an insulating layer 60, a semiconductor layer 30, and a cathode electrode layer 90.

Anode electrode layer 40 is connected to inductor L1 and switching element Q1 through power line PL1C. Metal layer 50 is formed between anode electrode layer 40 and semiconductor layer 30, and forms Schottky junction at a Schottky junction portion JP between semiconductor layer 30 and metal layer 50.

Polysilicon layer 55 is embedded in trench portion 70, and is made of polysilicon which is a conductive material. Insulating layer 60 is formed between polysilicon layer 55 and semiconductor layer 30, and is embedded in trench portion 70.

Although semiconductor layer 30 is made of silicon (Si) in the present embodiment, it may be made of a wide-gap semiconductor such as silicon carbide (SiC) or gallium nitride (GaN). Semiconductor layer 30 includes an n-type drift layer 80 and an n+ substrate layer 85.

n-type drift layer 80 is formed between metal layer 50 and n+ substrate layer 85. Equipotential lines in n-type drift layer 80 are represented by equipotential lines EPL.

n+ substrate layer 85 is formed to be adjacent to cathode electrode layer 90. Cathode electrode layer 90 is connected to load LOAD.

It should be noted that, unlike this example, an electric field in an n-type drift layer of a planar-type Schottky diode becomes stronger (the interval between equipotential lines becomes narrower) toward a Schottky junction portion, and is not uniform. Accordingly, a reverse voltage in the vicinity of the Schottky junction portion increases, and a breakdown voltage decreases. As a result, in the planar-type diode, a leak current is likely to increase, when compared with trench-type diode D1 having forward voltage Vf which is approximately equal to that of the planar-type diode.

On the other hand, in the present embodiment, diode D1 has trench portion 70, and functions in the same manner as a field plate. Thereby, the interval between equipotential lines EPL is substantially uniform. Accordingly, increase of electric field strength in the vicinity of Schottky junction portion JP is suppressed, and thus a breakdown voltage increases. As a result, in trench-type diode D1, a leak current is likely to decrease, when compared with the planar-type diode having forward voltage Vf which is approximately equal to that of trench-type diode D1.

FIG. 5 is a view illustrating an equivalent circuit of diode D1. Referring to FIG. 5, the equivalent circuit of diode D1 includes a rectification path P1 and a current path P2.

Rectification path P1 is a path through which the forward current from anode electrode layer 40 to cathode electrode layer 90 flows when the forward voltage is applied to diode D1. A capacitance component (parasitic capacitance) of rectification path P1 is represented by a capacitance Cd1. A resistance component of rectification path P1 is represented by a resistance Rd1, and a resistance Rd2 common to current path P2. Each of capacitance Cd1 and resistance Rd1 varies depending on the orientation and magnitude of an applied voltage of diode D1. When the forward voltage is applied to diode D1, a resistance value of resistance Rd1 decreases. When the reverse voltage is applied to diode D1, the resistance value of resistance Rd1 increases but the value is finite, and thus the leak current described above is generated.

Current path P2 is formed to be electrically parallel with rectification path P1. A capacitance component (parasitic capacitance) of current path P2 is represented by a capacitance Cs1. Capacitance Cs1 functions to make electric field distribution in diode D1 uniform (that is, to make the interval between equipotential lines EPL in FIG. 4 constant). A resistance component of current path P2 is represented by a resistance Rs1, and resistance Rd2 common to rectification path P1.

Capacitance Cs1 and resistance Rs1 are respectively a capacitance and a resistance of trench portion 70 of diode D1, and are specific to trench-type diode D1. That is, the planar-type Schottky diode does not have a capacitance component corresponding to capacitance Cs1 and a resistance component corresponding to resistance Rs1, whereas diode D1 includes capacitance Cs1 and resistance Rs1. Each of capacitance Cs1 and resistance Rs1 is determined, for example, according to the shape of trench portion 70, conductivity of polysilicon layer 55, and physical properties of the material for insulating layer 60.

Referring to FIGS. 1 and 2 again, preferably, the switching frequency of switching element Q1 is determined such that this frequency and its harmonic frequency do not interfere with a signal in a band of broadcast signal BS1 (signal for the AM broadcast). As described above, from the viewpoint of noise reduction, it is preferable that the switching frequency is higher than an upper limit frequency of the AM broadcast band.

In the present embodiment, the AM broadcast band is determined as a predetermined prohibited frequency band, and controller 5 controls switching element Q1 such that the switching frequency becomes higher than the upper limit frequency (1.71 MHz in this example) of the AM broadcast band.

Conventionally, there has been a problem that, when a DC/DC converter which drives a headlight of a vehicle is a boost converter connected with a battery, and the switching frequency of switching element Q1 is set to be higher than the upper limit frequency described above, power conversion efficiency of DC/DC converter 10 may be significantly reduced due to increased switching loss. As a result, it has been difficult to use a switching frequency higher than the upper limit frequency described above.

For the purpose of reducing switching loss, it seems preferable that switching element Q1 is formed using a MOSFET made of a wide-gap semiconductor such as silicon carbide (SiC) or gallium nitride (GaN).

However, when the switching frequency is set to be higher than an upper limit frequency of a prohibited frequency band in a boost converter which drives a headlight of a vehicle, just forming switching element Q1 using a MOSFET made of a wide-gap semiconductor is completely insufficient from the viewpoint of the effect of reducing loss. Further, there is also a problem that cost may significantly increase when specifications such as a withstand voltage of the MOSFET are not optimal, or when it is difficult to secure reliability against failures thereof.

The inventors have found that it is possible to suppress excessive reduction in power conversion efficiency of DC/DC converter 10, which is connected with battery 20 and has a boost function to drive headlight 1, even when controller 5 controls switching element Q1 at a switching frequency higher than 1.71 MHz. This finding will be described in detail below.

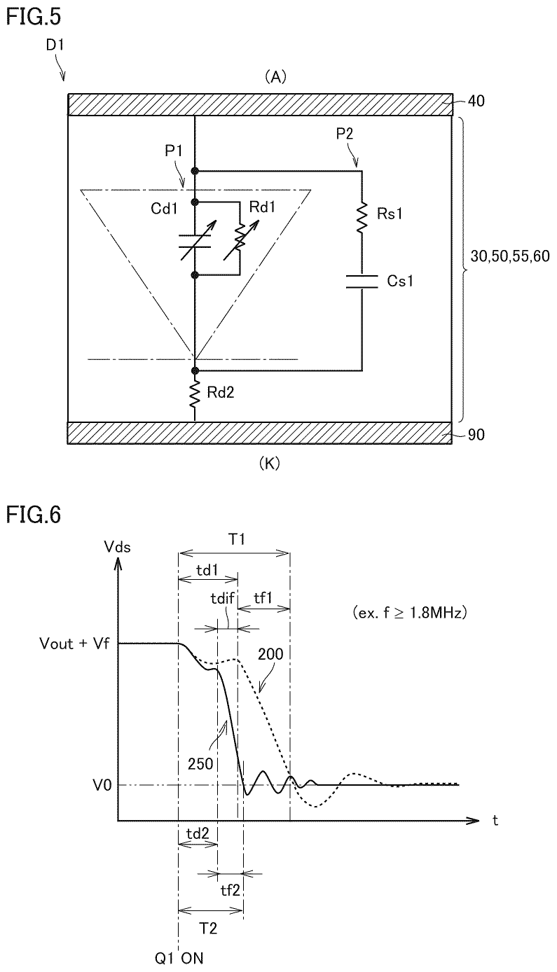

FIG. 6 is a view illustrating an example of transition of drain-source voltage Vds when switching element Q1 is switched from a turn-off state to a turn-on state. In this example, the switching frequency is more than or equal to 1.8 MHz (for example, 1.8 MHz, 1.9 MHz, 2.0 MHz, 2.1 MHz, or 2.2 MHz). In the following description, FIG. 2 will be referred to as appropriate.

Referring to FIG. 6, a broken line 200 indicates transition of voltage Vds in a comparative example. The comparative example is different from the present embodiment in that, instead of trench-type diode D1, a planar-type diode having forward voltage Vf which is approximately equal to that of trench-type diode D1 is used in a DC/DC converter. As described above, in both of the present embodiment and the comparative example, it is assumed that semiconductor layer 30 of diode D1 is made of silicon (Si).

A time td1 is a falling delay time of voltage Vds in the comparative example. A time tf1 is a falling time of voltage Vds in the comparative example. The falling delay time of voltage Vds is a time taken from a time point at which switching element Q1 is turned on to a time point at which voltage Vds starts to fall steeply and at a substantially constant gradient. The falling time of voltage Vds is a time taken from the time point at which voltage Vds starts to fall steeply and at a substantially constant gradient after switching element Q1 is turned on, to a time point at which voltage Vds reaches a voltage V0 (a reference voltage) for the first time.

A solid line 250 indicates transition of voltage Vds in the present embodiment. In the present embodiment, as described above, trench-type diode D1 having trench portion 70 is used in DC/DC converter 10. A time td2 is a falling delay time of voltage Vds in the present embodiment. A time tf2 is a falling time of voltage Vds in the present embodiment.

Time td2 is shorter than time td1. A time difference tdif between td1 and time td2 in the present embodiment is of the order of several nanoseconds or less. As time td1 becomes longer, time difference tdif becomes longer than 1 ns, for example, and thereby power supply efficiency of the DC/DC converter in the comparative example is exponentially reduced. On the other hand, in the present embodiment, since time td2 is short, power supply efficiency of DC/DC converter 10 in the present embodiment is significantly improved when time td2 becomes shorter only on the order of sub-nanoseconds, for example.

Referring to FIG. 5 again, a parasitic capacitance between the anode and the cathode of diode D1 in the present embodiment is the sum of capacitance Cd1 of rectification path P1 and capacitance Cs1 of current path P2. This summed capacitance is approximately equal to or more than a parasitic capacitance of the planar-type diode in the comparative example. Capacitance Cd1 of rectification path P1 of diode D1 in the present embodiment is smaller than the parasitic capacitance of the planar-type diode in the comparative example. That is, a reverse recovery time of diode D1 in the present embodiment is shorter than a reverse recovery time of the diode in the comparative example. A short reverse recovery time enables improved power supply efficiency of a DC/DC converter. The power supply efficiency of DC/DC converter 10 in the present embodiment is significantly improved due to a mechanism of generating time difference tdif, in addition to the short reverse recovery time. This generating mechanism will be described below.

Referring to FIG. 6 again, time difference tdif largely depends on a resonance frequency of voltage Vds immediately after switching element Q1 is turned on. The resonance frequency of voltage Vds largely depends on a parasitic capacitance and a parasitic inductance on a current path formed by switching element Q1, capacitor C1, and diode D1 of DC/DC converter 10. The resonance frequency also largely depends on output voltage Vout and output power Pout of DC/DC converter 10, a time point at which switching element Q1 is switched from the turn-off state to the turn-on state, the switching frequency, and the like.

In DC/DC converter 10 (a boost converter in this example) which drives headlight 1, typically, output voltage Vout is about 30 V to 70 V, and output power Pout is about 20 W to 200 W. In DC/DC converter 10 according to the present embodiment which is driven under this condition, since the switching frequency of switching element Q1 is set to be higher than 1.71 MHz (preferably, more than or equal to 1.8 MHz) and trench-type diode D1 is used, the resonance frequency of voltage Vds becomes higher than that in the comparative example. Thereby, time td2 in the present embodiment is shortened and time difference tdif is generated, and thus the power supply efficiency of DC/DC converter 10 is improved.

The resonance frequency of voltage Vds also has an influence on the falling time of voltage Vds described above as well. As a result, time tf2 in the present embodiment becomes shorter than time tf1 in the comparative example. In addition, in the present embodiment, a time T2 taken from a time point at which switching element Q1 is turned on to a time point at which voltage Vds reaches voltage V0 (the reference voltage) for the first time (=td2+tf2) becomes significantly shorter than a time T1 (=td1+tf1) taken in the comparative example (T2<<T1). As a result, in the present embodiment, switching loss in switching element Q1 can be significantly reduced. Therefore, even when controller 5 controls switching element Q1 at a switching frequency higher than 1.71 MHz (for example, more than or equal to 1.8 MHz), it is possible to suppress excessive reduction in power conversion efficiency of DC/DC converter 10, while avoiding interference of noise with broadcast signal BS1.

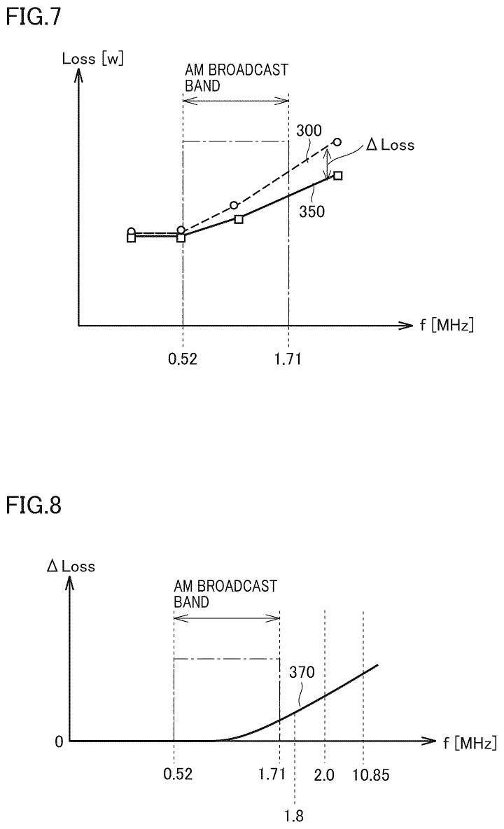

FIG. 7 is a view illustrating an example of the relation between a total loss of DC/DC converter 10 and the switching frequency of switching element Q1. The total loss of DC/DC converter 10 is the sum of losses of inductor L1, switching element Q1, diode D1, and capacitor C1 (FIG. 2).

Referring to FIG. 7, a broken line 300 indicates the relation between a total loss Loss and a switching frequency f in the comparative example, and a solid line 350 indicates the relation between total loss Loss and switching frequency f in the present embodiment. It is assumed that a total loss difference ΔLoss is a difference between total loss Loss in the comparative example (broken line 300) and total loss Loss in the present embodiment (solid line 350).

FIG. 8 is a view illustrating an example of the relation between total loss difference ΔLoss between the DC/DC converters and switching frequency f. The relation in FIG. 8 is based on the relation in FIG. 7. Referring to FIG. 8, a line 370 indicates a manner in which total loss difference ΔLoss changes as switching frequency f increases.

At a frequency lower than the AM broadcast band (a frequency lower than 0.52 MHz), total loss difference ΔLoss is not so significant. In the AM broadcast band, total loss difference ΔLoss starts to become significant as switching frequency f increases. At a frequency higher than the AM broadcast band (for example, 2.0 MHz), total loss difference ΔLoss becomes more significant, and the advantage of the present embodiment over the comparative example further stands out. That is, total loss Loss in the present embodiment is significantly reduced, when compared with that in the comparative example.

The MOSFET as switching element Q1 may be the one which includes a semiconductor made of silicon and has a small total charge amount (Qg) of about 15 nC or less. As a result, it is possible to manufacture DC/DC converter 10 at a lower price and with higher reliability against failures. Further, it is possible to suppress excessive reduction in power conversion efficiency of DC/DC converter 10, while avoiding interference of noise with broadcast signal BS1.

It should be noted that, from the viewpoint of avoiding interference of noise with a signal in the FM broadcast band, switching frequency f is set to be higher than at least 1.71 MHz (preferably, more than or equal to 1.8 MHz) and less than or equal to 10.85 MHz. This will be described in detail later.

FIG. 9 is a view illustrating an example of a spectrum of frequency of noise generated due to switching operation of switching element Q1 of DC/DC converter 10. Referring to FIG. 9, the axis of ordinate indicates intensity I of the noise (maximum value: Imax), and the axis of abscissa indicates a noise frequency component fn. The scale on the axis of abscissa does not necessarily coincide with the actual scale of the frequency component.

Noise frequency component fn is a frequency component of noise generated when switching element Q1 is turned on/off in DC/DC converter 10. Although it is assumed in this example that noise frequency component fn is a frequency component of conduction noise of input current Iin (FIG. 2), noise frequency component fn may be a frequency component of radiation noise generated from DC/DC converter 10.

A line 400 indicates a spectrum of noise frequency component fn. This spectrum is derived by fast Fourier transformation (FFT) of input current Iin. This spectrum may be derived by FFT of a noise terminal voltage obtained from a line impedance stabilization network (LISN) provided between battery 20 and DC/DC converter 10. A band Δf is a half-value width band in the spectrum described above (in other words, a half-value width band with a peak frequency fp1 corresponding to switching frequency f).

In this example, switching frequency f is determined such that a condition that a lower limit frequency f1 of band Δf becomes higher than the upper limit frequency (1.71 MHz) of the AM band (a first condition) is satisfied. That is, controller 5 controls switching element Q1 such that lower limit frequency f1 becomes higher than the upper limit frequency of the AM band. Thereby, it is possible to suppress reduction in power conversion efficiency, while more reliably avoiding interference of noise with a signal in the AM band. As an example, when band Δf is narrow, switching frequency f is determined such that lower limit frequency f1 of band Δf is set to more than or equal to 1.8 MHZ.

The width of band Δf varies depending on the waveform of voltage Vds while switching element Q1 is operated. Examples of switching frequency f at which the first condition is surely satisfied include 2.0 MHz. Switching frequency f at which the first condition is satisfied may be more than or equal to 2.0 MHz, and may be 2.1 MHZ or 2.2 MHz, for example.

Alternatively, switching frequency f may be determined such that a condition that a frequency obtained by subtracting 3σ from peak frequency fp1 becomes higher than 1.71 MHz (a second condition) is satisfied, where σ is the standard deviation of the spectrum. The value of switching frequency f which satisfies the first or second condition is predetermined through experiments, for example.

When switching frequency f is determined such that the first or second condition is satisfied, it is possible to suppress reduction in power conversion efficiency, while more reliably preventing interference of noise due to switching operation of switching element Q1, with broadcast signal BS1.

Preferably, the noise generated in the DC/DC converter does not interfere with not only broadcast signal BS1 but also broadcast signal BS2 (signal for the FM broadcast). Accordingly, controller 5 may control switching element Q1 such that, in addition to the first condition that peak frequency fp1, that is, switching frequency f, is higher than the upper limit frequency (1.71 MHz) of the AM broadcast band, a condition that an n-th harmonic component (a frequency component fpn (n≥2)) of peak frequency fp1 is not included in the FM broadcast band (a third condition), are satisfied.

Practically, interference of noise with a signal in the FM band can be basically avoided when a seventh harmonic (n=7) is set to be lower than a lower limit frequency (76 MHz in the present embodiment) of the FM band. Thus, controller 5 may control the switching element such that a seventh harmonic component is not included in the FM broadcast band (more specifically, such that the seventh harmonic component becomes lower than the lower limit frequency of the FM broadcast band). Specifically, switching frequency f may be set to be within a range of higher than 1.71 MHz and less than or equal to 10.85(≈76/7) MHz. More preferably, switching frequency f is set to be within a range of more than or equal to 1.8 MHz and less than or equal to 10.85 MHz. More preferably, switching frequency f may be set to be within a range of more than or equal to 2.0 MHz and less than or equal to 10.85 MHZ, such that the first condition is further satisfied.

In order to more reliably prevent interference of noise due to the n-th harmonic component with a signal in the FM broadcast band, a fourteenth harmonic (n=14) may be set to be lower than 76 MHz. Thus, controller 5 may control the switching element such that a fourteenth harmonic component is not included in the FM broadcast band (more specifically, such that the fourteenth harmonic component becomes lower than the lower limit frequency of the FM broadcast band). Specifically, switching frequency f may be set to be higher than 1.71 MHz and less than or equal to 5.42 (≈76/14) MHz. More preferably, switching frequency f is set to be within a range of more than or equal to 1.8 MHz and less than or equal to 10.85 MHz. More preferably, switching frequency f may be set to be within a range of more than or equal to 2.0 MHz and less than or equal to 5.42 MHz, such that the first condition is further satisfied.

It should be noted that the AM broadcast band corresponds to an example of a “first prohibited frequency band” in the present disclosure, and the FM broadcast band corresponds to an example of a “second prohibited frequency band” in the present disclosure.

When switching frequency f is set such that the third condition described above is satisfied, it is possible to prevent interference of noise due to switching operation of switching element Q1, with broadcast signal BS2. Therefore, DC/DC converter 10 can drive headlight 1 while suppressing reduction in power conversion efficiency and preventing noise due to the switching operation from interfering with both broadcast signals BS1 and BS2.

Controller 5 may control switching element Q1 such that, in addition to the first condition described above, a condition that intensity I of the seventh harmonic (or the fourteenth harmonic) is set to substantially 0 in the FM broadcast band (a fourth condition), are satisfied. Intensity I of substantially 0 means, for example, that intensity I is the number which is more than 0 and less than a predetermined positive value. The predetermined positive value is determined such that, when intensity I is equal to this positive value, influence of switching noise on broadcast signal BS2 is negligible from a practical viewpoint. Examples of the predetermined positive value include a limit value of intensity I prescribed by the standard for Electromagnetic Compatibility (EMC).

As described above, according to the present embodiment, even when controller 5 controls switching element Q1 at switching frequency f higher than the upper limit frequency of the AM broadcast band, it is possible to suppress excessive reduction in power conversion efficiency, while avoiding interference of noise with broadcast signal BS1.

Further, unlike a case where the switching frequency is lower than the AM broadcast band, it is possible to avoid the harmonic component of switching frequency f from interfering with broadcast signal BS1. Therefore, there is no need to add an extra input noise filter or the like to between battery 20 and DC/DC converter 10, for example. In addition, in the present embodiment in which switching frequency f is higher when compared with the case described above, an inductance value of inductor L1 and a resistance value of a DC component can be reduced. Thereby, downsizing of inductor L1 and reduction of the amount of heat generation can both be achieved. As a result, manufacturing cost of DC/DC converter 10 can be reduced.

Since diode D1 in the present embodiment is a Schottky diode, it is suitable for fast switching. Further, since a leak current is likely to decrease as described above, diode D1 operates stably also when temperature increases. With such a configuration, fast switching at switching frequency f higher than the upper limit frequency of the AM broadcast band can be performed appropriately. Thereby, even when switching frequency f is higher than the upper limit frequency of the AM broadcast band, DC/DC converter 10 can operate appropriately.

Semiconductor layer 30 of diode D1 in the present embodiment is made of silicon (Si). Thereby, a product with an optimal reverse voltage can be easily selected or manufactured as diode D1. Therefore, downsizing and cost reduction of diode D1 can both be achieved, and further, diode D1 can also have higher reliability against failures. As a result, it is possible to manufacture DC/DC converter 10 at a low cost, while achieving downsizing and higher reliability thereof. Furthermore, since the withstand voltage of diode D1 is several tens of volts to 100 V, it is suitable for the drive voltage (30 V to 70 V) of headlight 1 of vehicle 100.

DC/DC converter 10 is mounted on vehicle 100, and is connected to battery 20. Although input voltage Vin corresponding to the voltage of battery 20 is typically 12 V, it may instantaneously fall to about 6 V. Accordingly, DC/DC converter 10 receives large input current Iin from battery 20 to drive headlight 1. According to the present embodiment, even when such large input current Iin is supplied to DC/DC converter 10, headlight 1 can be driven while avoiding interference of noise with broadcast signal BS1 (and broadcast signal BS2) and suppressing reduction in power conversion efficiency.

### Variation

Although it is assumed in the embodiment described above that DC/DC converter 10 is a boost converter, it may be replaced by a buck-boost converter.

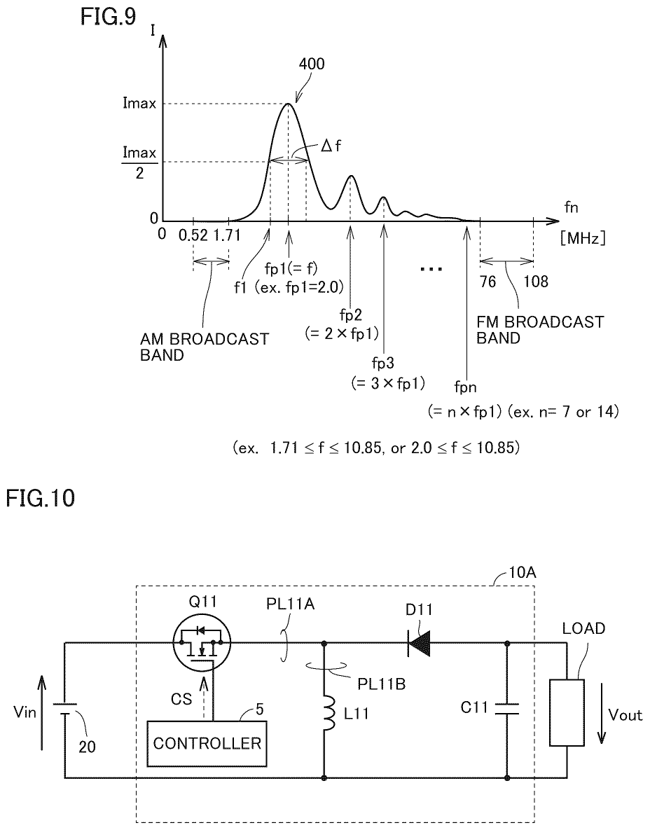

FIG. 10 is a view illustrating an example of a configuration of a DC/DC converter in this variation. Referring to FIG. 10, a DC/DC converter 10A is buck-boost converter of an asynchronous type, and is configured to boost input voltage Vin to output voltage Vout. DC/DC converter 10A includes a switching element Q11, an inductor L11, a diode D11, a capacitor C11, and controller 5.

Switching element Q11 is connected to inductor L11 in series, and is controlled by controller 5. Diode D11 is a trench-type diode (FIG. 4) as with diode D1, and is connected between power lines PL11A, PL11B and load LOAD. Power lines PL11A and PL11B are provided between inductor L11 and switching element Q11.

In the present embodiment, it is assumed that the number of LEDs 3A to 3Z is large and the voltage applied to LED array 3 is higher than the voltage of battery 20. That is, DC/DC converter 10A performs operation in a boost mode. It should be noted that, when the number of LEDs 3A to 3Z is small and the voltage applied to LED array 3 is lower than the voltage of battery 20, DC/DC converter 10A may operate in a voltage lowering mode.

Also in DC/DC converter 10A, a resonance frequency of voltage Vds immediately after switching element Q11 is turned on becomes higher than a resonance frequency in a case where a planar-type diode is used as diode D11. As a result, the same advantage as that in the embodiment described above (the advantage of trench-type diode D11) is obtained when a switching frequency is set to be higher than 1.71 MHz in DC/DC converter 10A. The resonance frequency of voltage Vds is determined by a parasitic capacitance and a parasitic inductance on a current path formed by switching element Q11, capacitor C11, diode D11, and an input capacitor (not shown), and output voltage Vout, output power Pout, the switching frequency, and the like.

Consequently, it is possible to suppress reduction in power conversion efficiency while avoiding interference of noise with broadcast signal BS1 (and broadcast signal BS2), as in the embodiment described above.

It should be noted that DC/DC converter 10A may be a Cuk converter, a Zeta converter, or a Sepic converter (Single Ended Primary Inductor Converter).

### Other Variations

Referring to FIG. 3 again, when the number of LEDs 3A to 3Z is small and the voltage applied to LED array 3 is lower than the voltage of battery 20, DC/DC converter 10 may be replaced by a buck converter of an asynchronous type. Alternatively, buck converter 2 which performs constant current control shown in FIG. 3 may be a converter of an asynchronous type. In this case, the embodiment described above or the variation thereof may be applied to buck converter 2. Specifically, a switching frequency of a switching element of buck converter 2 may be set to be higher than 1.71 MHz, and a trench-type diode may be used as a diode of buck converter 2.

Although it is assumed in the embodiment described above that semiconductor layer 30 is made of silicon, it may be made of a semiconductor different from silicon (for example, SiC, GaN).

DC/DC converter 10 may be used for an application different from driving headlight 1 of vehicle 100. If a parameter such as voltage, current, power, or switching frequency of each component of DC/DC converter 10 is equal to a parameter for driving headlight 1 of vehicle 100, the same advantage as that in the embodiment described above and the variation thereof is obtained.

The “second prohibited frequency band” in the present disclosure is not limited to the FM broadcast band, and may be a band (26.5 MHz to 29.7 MHz) of a citizens band (CB: Citizens Band Radio) broadcast, for example.

It should be understood that the embodiment disclosed herein is illustrative and non-restrictive in every respect. The scope of the present disclosure is defined by the scope of the claims, rather than the description above, and is intended to include any modifications within the scope and meaning equivalent to the scope of the claims.

### REFERENCE SIGNS LIST

1: headlight; 5: controller; 10, 10A: DC/DC converter; 20: battery; 25: radio; 100: vehicle; C1, C11: capacitor; Cd1, Cs1: capacitance; D1, D11: diode; L1, L11: inductor; LOAD: Load; P1: rectification path; P2: current path; Q1, Q11: switching element.

1. A DC/DC converter of an asynchronous type, comprising:
an inductor;
a switching element connected to the inductor in series;
a diode connected to the inductor and the switching element; and
a controller to control the switching element, wherein
the controller controls the switching element such that a switching frequency of the switching element becomes higher than an upper limit frequency of a predetermined frequency band, and
the diode includes
a first capacitance which is a capacitance of a rectification path through which a forward current of the diode flows, and
a second capacitance which is a capacitance of a current path formed in parallel with the rectification path.

2. The DC/DC converter according to claim 1, wherein
the diode is a trench-type diode, and
the second capacitance is a capacitance of a trench portion of the diode.

3. The DC/DC converter according to claim 1, wherein the predetermined frequency band is an AM broadcast band.

4. The DC/DC converter according to claim 1, wherein the upper limit frequency is 1.71 MHz.

5. The DC/DC converter according to claim 1, wherein the controller controls the switching element such that a lower limit frequency of a half-value width band of a spectrum of noise generated due to switching operation of the switching element becomes higher than the upper limit frequency.

6. The DC/DC converter according to claim 1, wherein the switching frequency is within a range of higher than 1.71 MHz and less than or equal to 10.85 MHz.

7. The DC/DC converter according to claim 6, wherein the switching frequency is within a range of more than or equal to 2.0 MHz and less than or equal to 10.85 MHz.

8. The DC/DC converter according to claim 1, wherein the diode is a Schottky diode.

9. The DC/DC converter according to claim 1, wherein
the diode includes a semiconductor layer, and
the semiconductor layer is made of silicon.

10. The DC/DC converter according to claim 1, wherein
the inductor is connected between a positive electrode node of a power source for the DC/DC converter and the switching element,
the switching element is connected between the inductor and a negative electrode node of the power source, and
an anode of the diode is connected to the inductor and the switching element.

11. The DC/DC converter according to claim 10, wherein
the DC/DC converter is configured to be mounted on a vehicle,
the power source is a battery of the vehicle, and
a load for the DC/DC converter is configured to include a headlight of the vehicle.

12. The DC/DC converter according to claim 1, wherein the controller controls the switching element such that a seventh harmonic component of the switching frequency is not included in a second frequency band which is higher than a first frequency band as the predetermined frequency band.

13. The DC/DC converter according to claim 1, wherein the controller controls the switching element such that a fourteenth harmonic component of the switching frequency is not included in a second frequency band which is higher than a first frequency band as the predetermined frequency band.

14. The DC/DC converter according to claim 12, wherein the second frequency band is an FM broadcast band.

15. The DC/DC converter according to claim 12, wherein the second frequency band includes a frequency band of more than or equal to 76 MHz and less than or equal to 108 MHz.
